(19) United States
(12) Patent Application Publication
(10) Pub. No.: US 2015/0013758 A1
(43) Pub. Date: Jan. 15, 2015

(54) PROCESS FOR TREATING A HETEROJUNCTION PHOTOVOLTAIC CELL

(71) Applicants: Samuel Harrison, Pontcharra (FR); Pierre-Jean Ribeyron, Saint Ismer (FR)

(72) Inventors: Samuel Harrison, Pontcharra (FR); Pierre-Jean Ribeyron, Saint Ismer (FR)

(73) Assignee: COMMISSARIAT A L'ENERGIE ATOMIQUE ET AUX ENERGIES ALTERNATIVES, Paris (FR)

(21) Appl. No.: 14/129,362

(22) PCT Filed: Jun. 25, 2012
(86) PCT No.: PCT/IB2012/053204

§ 371 Date: Jan. 30, 2014

(30) Foreign Application Priority Data
Jun. 27, 2011 (FR) 1155716

(51) Int. Cl. H01L 31/0747; H01L 31/18; H01L 31/0224; H01L 31/0216

(52) U.S. Cl. CPC H01L 31/0747; H01L 31/02167; H01L 31/1804; H01L 31/022433; H01L 31/02168
USPC 136/256; 438/72

(57) ABSTRACT

The invention provides a process for treating an n-type photovoltaic cell free from all but trace amounts of boron atoms, said process comprising the following steps: providing an n-type heterojunction photovoltaic cell (10) comprising a central crystalline silicon layer (1) on and under which two passivation layers (2, 3) made of hydrogenated amorphous silicon are deposited; heating this cell to a temperature between 20° C. and 200° C., for example on a hot plate (20) or in an oven (40), while illuminating the photovoltaic cell with a light flux from a light source (30). The efficiency of the photovoltaic cell is thus improved and stabilized.

The invention relates to a process for treating photovoltaic cells in order to improve and stabilize their efficiency.

Heterojunction photovoltaic cells are formed by associating two semiconductors: crystal silicon and amorphous silicon, as opposed to homojunction cells which are formed by associating two zones of the same material.

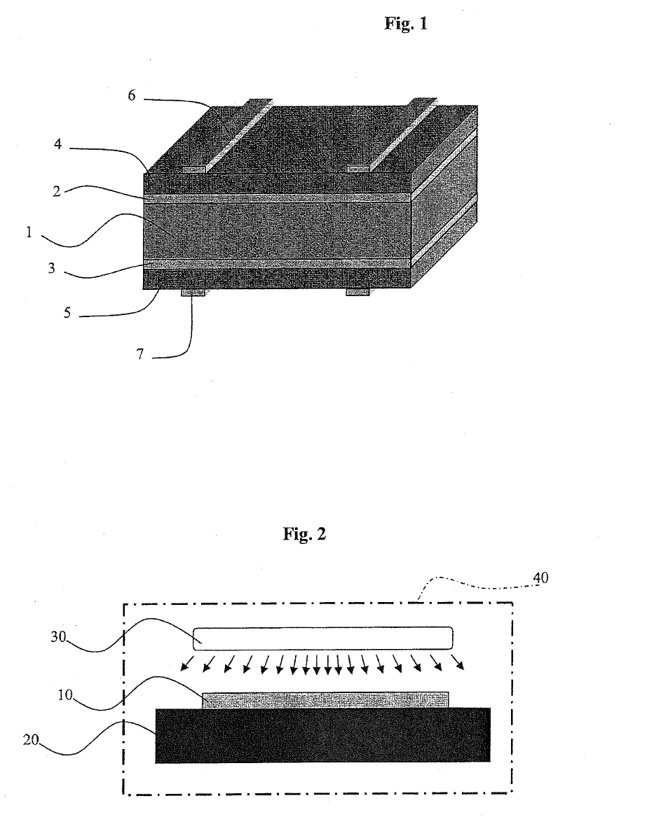

More particularly, a heterojunction cell comprises, with reference to FIG. 1, a central layer made of crystal silicon, on and under which two layers 2 and 3, called “passivation” layers, made of amorphous silicon are placed, i.e. an upper layer 2 and a lower layer 3.

The silicon substrate used as a central layer 1 is a (CZ or FZ) crystal substrate that is n-type, i.e. it in particular contains no boron atoms in its bulk, except in trace amounts (a trace amount is defined, in the present invention, as being a boron, denoted [B], concentration comprised between 0 and 1×10¹⁶ at/cm³).

In the context of the invention, the passivation layers 2 and 3 are made of hydrogenated amorphous silicon (a-Si:H).

The crystal silicon substrate 1 must contain the smallest amount of impurities possible in order to maximize the performance of the photovoltaic cell. Likewise, the interface between the crystal silicon 1 and the layers 2 and 3 of amorphous silicon a-Si:H must be cleaned and passivated as perfectly as possible before deposition in order to guarantee a very good voltage across the terminals of the cell. These cleans have the objective of removing organic and metal particles, but also of saturating all the residual surface defects on the surface with hydrogen. A certain number of different cleans of varying effectiveness exist for improving the passivation. Likewise, the passivation may be improved by varying the nature of the amorphous silicon layer 2-3, its thickness and doping.

Each amorphous silicon layer 2-3 is covered with a layer, an upper 4 and lower 5 layer, respectively, of a transparent electrically conductive oxide.

Metal electrodes 6 are placed on the free side of the transparent electrically conductive oxide layer 4, called the “frontside” because it is intended in use to receive the light flux, and metal electrodes 7 are placed on the free side of the transparent electrically conductive oxide layer 5, called the “backside”, as opposed to the frontside.

The electrodes 6 consist of a metal grid, in order to allow photons to pass into the silicon layers 1, 2 and 3.

The electrodes 7 may either be a grid (like the electrodes 6), or a continuous layer. In this case, photons cannot pass through this opaque layer to reach the silicon layers 1, 2 and 3.

The article by De Wolf et al. (Physical Review B, vol. 83, no. 23, 7 June 2011, pages 233301-1-233301-4, XP55025598) studies the influence of light induced degradation (LID) on an area made of crystal silicon passivated with hydrogenated amorphous silicon. The aim of this study is to analyze the nature and stability of bulk and interface defects in the amorphous silicon by way of the parameter τeff (charge carrier lifetime) which only defines the quality of the passivation. This article does not propose any improvements, or even stabilization of the performance (in particular the efficiency) of a heterojunction photovoltaic cell. On the contrary, this article shows (FIG. 1b) that the variation of this coefficient as a function of time under illumination is not very good for a-Si:H/c-Si(111) and for a-Si:H/c-Si(100), since after a slight improvement, it declines after 6 hours.

In order to improve the efficiency of a photovoltaic cell, it has already been proposed to subject the cell to a heat treatment (heating of the cell to a temperature comprised between 50° C. and 230° C.) while the cell is under voltage. This type of treatment has always been reserved for cells made of silicon doped with boron atoms. Specifically, such cells may see their energy conversion efficiency decreased during use (i.e. when they are illuminated). This effect is related to the formation, during illumination, of complexes that associate a boron atom in a substitutional position (Bₛ) and an oxygen dimer (Oᵢ₂). During illumination, the mobile oxygen dimer diffuses toward the immobile boron atom. The complex formed introduces a deep energy level into the bandgap of the silicon, thereby allowing free charges to recombine, and consequently decreasing the lifetime of the charge carriers and the energy conversion efficiency of the cell.

For an n-type heterojunction cell (i.e. one in which the silicon substrate used for the central layer 1 contains no boron, except in trace amounts), the Applicant has discovered that such a treatment can be adapted to improve the efficiency of this cell, even though this cell contains no boron, except in trace amounts.

The object of the invention is therefore to provide a process for treating n-type photovoltaic cells containing no boron.

For this purpose, the invention proposes to illuminate the n-type heterojunction cell during a heat treatment carried out at a temperature comprised between 20 and 200° C.

More particularly, the invention relates to a process for treating n-type photovoltaic cells in order to improve and stabilize their efficiency, said process comprising the following steps:
providing an n-type heterojunction photovoltaic cell comprising a central crystal silicon layer on and/or under which a passivation layer made of hydrogenated amorphous silicon is placed; and
heating this cell to a temperature comprised between 20° C. and 200° C. for a set processing time, while subjecting the photovoltaic cell to a set light flux.

In other embodiments:
the light flux may be higher than or equal to 100 W/m², preferably higher than or equal to 250 W/m², and advantageously higher than or equal to 500 W/m²;
the set processing time may be less than 48 hours, is preferably comprised between 30 minutes and 12 hours, and is advantageously about 10 hours;
the heating temperature may be preferably comprised between 20° C. and 150° C., and advantageously between 35° C. and 80° C., and typically between 55° C. and 80° C.;
the heating step under illumination may be continuous or sequential; and
the n-type heterojunction photovoltaic cell provided may comprise metal electrodes on its surface and/or an antireflective layer promoting, thus, the penetration of photons into the cell.

The invention also relates to a photovoltaic cell obtained by the above process, having an absolute open-circuit voltage value |V_{oc}| higher than the initial absolute value |V_{o|}ᵢₙᵢₜᵢₐₗ.

Other features of the invention will be set out in the following detailed description given with reference to the appended figures, which show, respectively:

FIG. 1, a schematic perspective view of a heterojunction cell used in the context of the invention;

FIG. 2, a schematic cross-sectional view of an apparatus for implementing the process according to the invention;

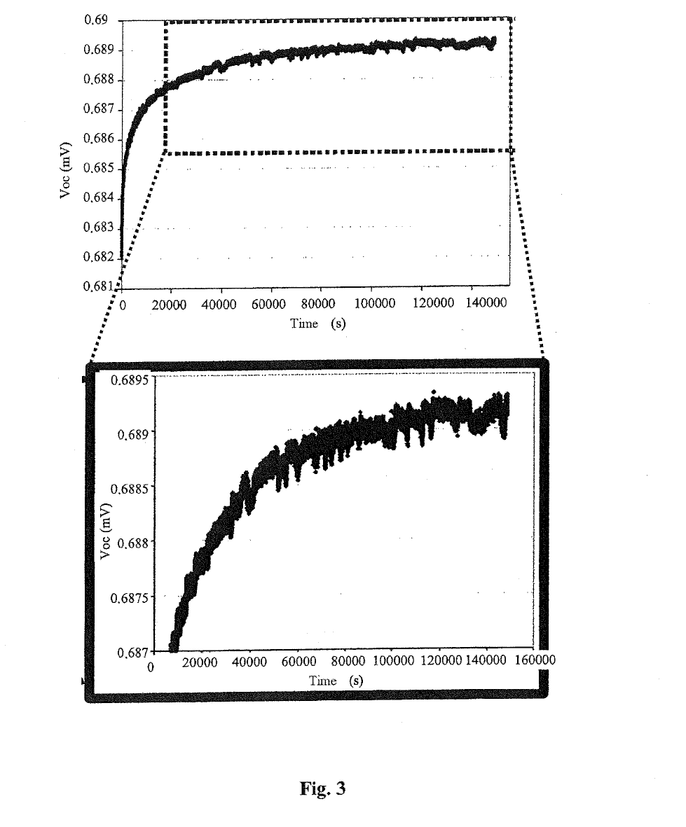

FIG. 3, a graph illustrating the improvement in the passivation of a heterojunction cell undergoing a treatment according to the invention; and

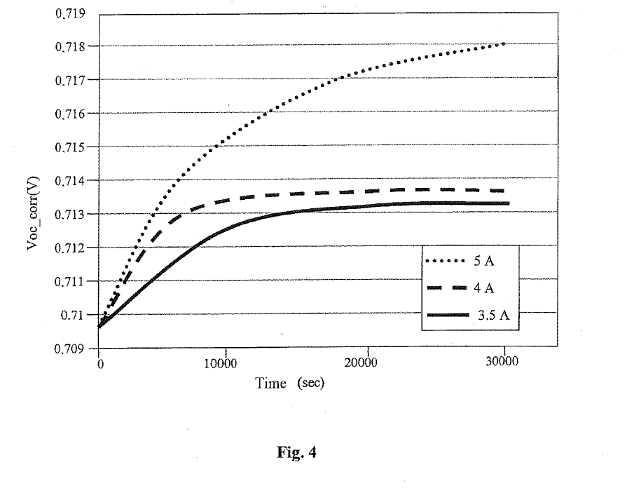

FIG. 4, a graph illustrating the impact of the intensity of the incident illuminating flux on the final improvement in the passivation of a heterojunction cell, for flux intensities between 3.5 and 5 A.

The process for treating photovoltaic cells according to the invention comprises a first step of providing a heterojunction photovoltaic cell that is re-type, i.e. that contains no boron atoms, except in trace amounts (boron, denoted [B], concentration comprised between 0 and b 1×10¹⁶ at/cm³). The cell comprises a central layer 1 made of crystal silicon on and under which two passivation layers 2 and 3 made of hydrogenated amorphous silicon are placed.

Advantageously, at least one of the amorphous silicon layers 2 and/or 3 is doped or micro-doped. The layer 2 may more particularly be doped (or micro-doped) with a p-type dopant and the layer 3 may be doped (or micro-doped) with an n-type dopant. In one particular case, the layer 3 may be intrinsic, i.e. undoped (an intrinsic semiconductor is a semiconductor the electrical behavior of which depends only on its structure, and not on the addition of impurities as in the case of doping. In an intrinsic semiconductor, charge carriers are created only by crystal defects and by thermal excitation. The number of electrons in the conduction band is equal to the number of holes in the valence band).

Preferably, the amorphous silicon layers 2 and/or 3 have a thickness smaller than or equal to 35 nm. In the case where the layers 2 and/or 3 are made of doped (or micro-doped) amorphous silicon, their thickness is advantageously comprised between 15 and 20 nm. In the case where the layer 3 is made of intrinsic a-Si, its thickness is advantageously smaller than or equal to 10 nm.

Next, the cell is heated to a temperature comprised between 20° C. and 200° C. for a set processing time, while the photovoltaic cell is subjected to a set light flux.

Preferably, the temperature of the heating step under illumination is comprised between 20° C. and 150° C., advantageously between 35° C. and 80° C., and typically between 55° C. and 80° C.

This step of heating under illumination carried out during the process for treating n-type photovoltaic cells is not preceded by a long annealing step (for example at a temperature of 220° C.). The only annealing step liable to be carried out at a temperature of about 200° C. is that carried out to fabricate the metallizations of the cell.

The treatment may be carried out in open air or in a heating chamber, such as an oven. There is no need to carry out the treatment in a chamber with a controlled pressure, atmosphere or humidity.

A simplified schematic of the device used is shown in FIG. 2. The cell in question 10 is placed on a hot plate 20 and under a light source 30.

It is possible to work with one or more light sources.

Furthermore, the hot plate 20 may be replaced with an oven 40 at the desired temperature.

Thus, the invention described proposes to further improve surface passivation for a given deposited active layer/clean combination without making changes to the cleaning processes or the nature of the layers, which changes have already been explored in depth. The illumination at temperature is performed after steps of cleaning and of depositing the passivating layers 2 and 3. It may moreover then be performed either during fabrication of the cell (layers 4-5 and/or electrodes 6-7 not deposited), or on a finished cell (layers 4-5 and electrodes 6-7 deposited).

In the case where the process according to the invention is applied to a finished cell, for a conventional heterojunction cell with a metallization grid on the frontside and backside, the light flux may either be applied via the frontside or via the backside. In the case where an opaque metallization is used on the backside (continuous metal layer for example), the illumination must necessarily be applied to the frontside.

An example of the improvement in the passivation (Voc) as a function of illumination time is shown in FIG. 3. A continuous improvement in the passivation, which tends to saturate over time, will be noted. In other words, for constant illumination and heating, it is pointless to continue the treatment beyond a threshold length of time.

The treatment time according to the invention is less than 48 hours, and is preferably comprised between 30 minutes and 12 hours. Advantageously, the treatment time is about 10 hours for a light flux of at least 100 W/m², preferably higher than or equal to 250 W/m², and advantageously higher than or equal to 500 W/m².

Regarding the illumination, it is necessary to provide a sufficient amount of energy to correctly activate the process.

Generally, the higher the light intensity, the greater and more rapid the effect on efficiency. It is thus advantageous, from an industrial point of view, to employ a treatment process using a high illumination power.

Preferably, the cell is illuminated with a halogen bulb having a power of 500 W or more. However, an improvement in the passivation is observed whatever the power of the incident illumination. However, the more the intensity of the illumination decreases, the more the improvement in the passivation will be smaller and above all, with regard to industrialization of the process, the more the kinetics of the reaction will be slowed. Thus, as FIG. 4 shows, the power of the illumination has a critical effect on the magnitude and kinetics of the improvement in the passivation. For equal heating temperatures, cells illuminated with a light flux intensity of 3.5 A (solid line) and of 4 A (dashed line) saturate much more rapidly than a cell illuminated with a light flux intensity of 5 A (dotted line), and at a lower passivation value.

To determine the high power limit of the illumination to be applied, depending on the features of the cell to be treated, it is necessary to take into account heating of the cell caused by the illumination. Specifically, n-type heterojunction cells degrade at temperatures of 200° C. or more. It is therefore necessary to take care that the intensity of the incident light flux is limited in terms of heating, because the latter adds to the heat delivered by the hot plate or oven.

According to the invention, the heating temperature of the plate or oven is comprised between 20 and 200° C., and advantageously between 35 and 80° C. This is highly dependent on the type of substrate and on the type of passivation layer used.

According to other features of the invention, the n-type heterojunction photovoltaic cell may also be an RCC, i.e. all the metallizations and active layers are grouped together on the backside of the cell. The back surface may then be the only one passivated by a hydrogenated amorphous layer deposit. The frontside deposit is therefore unimportant, provided that it is as transparent as possible to the incident light flux, and that it provides a good surface passivation.

Moreover, the process according to the invention is advantageously continuous, but it may be sequential, i.e. it may be interrupted then restarted.

The n-type heterojunction photovoltaic cell provided may comprise an antireflective layer promoting, thus, the penetration of photons into the cell.

1. A process for treating n-type photovoltaic cells containing no boron atoms except in trace amounts, in order to improve and stabilize their efficiency, said process comprising the following steps:
providing an n-type heterojunction photovoltaic cell comprising a central crystal silicon layer (1) on and/or under which a passivation layer (2-3) made of hydrogenated amorphous silicon is placed; and
heating this cell to a temperature comprised between 20° C. and 200° C. for a set processing time, while subjecting the photovoltaic cell to a set light flux.

2. The treatment process as claimed in claim 1, in which the light flux is higher than or equal to 100 W/m², preferably higher than or equal to 250 W/m², and advantageously higher than or equal to 500 W/m².

3. The treatment process as claimed in claim 1, in which the set processing time is less than 48 hours, is preferably comprised between 30 minutes and 12 hours, and is advantageously about 10 hours.

4. The treatment process as claimed in claim 1, in which the heating temperature is preferably comprised between 20° C. and 150° C., and advantageously between 35° C. and 80° C., and typically between 55° C. and 80° C.

5. The treatment process as claimed in claim 1, in which the heating step under illumination is continuous or sequential.

6. The treatment process as claimed in claim 1, in which the n-type heterojunction photovoltaic cell provided comprises metal electrodes (6-7) on its surface.

7. The treatment process as claimed in claim 1, in which the n-type heterojunction photovoltaic cell comprises at least one antireflective layer.

8. A photovoltaic cell obtained by the process as claimed in claim 1, characterized in that it has an absolute open-circuit voltage value |V_{oc}| higher than the initial absolute value |V_{oc}|ᵢₙᵢₜᵢₐₗ.
